(19) United States
(12) Patent Application Publication
(10) Pub. No.: US 2015/0090578 A1
(43) Pub. Date: Apr. 2, 2015

(54) TOUCH PANEL AND METHOD OF MANUFACTURING THE SAME

(71) Applicant: SAMSUNG ELECTRO-MECHANICS CO., LTD., Suwon (KR)

(72) Inventors: Jang Bae SON, Suwon (KR); Kang Heon Hur, Suwon (KR); Sang Hoon Park, Suwon (KR); Hyun Chul Jung, Suwon (KR)

(73) Assignee: SAMSUNG ELECTRO-MECHANICS CO., LTD., Suwon (KR)

(21) Appl. No.: 14/132,559

(22) Filed: Dec. 18, 2013

(30) Foreign Application Priority Data
Sep. 30, 2013 (KR) 10-2013-0116097

(51) Int. Cl. H03K 17/96

(52) U.S. Cl. CPC H03K 17/962; H03K 2017/9602; H03K 2217/960755
USPC 200/600; 427/58; 427/125; 427/123

(57) ABSTRACT

There is provided a touch panel including: a substrate; mesh pattern electrodes formed on the substrate; and hard coating layers formed on the substrate and filling air gaps of the mesh pattern electrode.

### CROSS-REFERENCE TO RELATED APPLICATION

This application claims the benefit of Korean Patent Application No. 10-2013-0116097 filed on Sep. 30, 2013, with the Korean Intellectual Property Office, the disclosure of which is incorporated herein by reference.

### BACKGROUND

The present disclosure relates to a touch panel and a method of manufacturing the same.

A touch sensing apparatus such as a touchscreen, a touchpad, or the like, a data input apparatus attached to a display apparatus to provide an intuitive data input method to a user, has recently been widely used in various electronic devices such as cellular phones, personal digital assistants (PDA), navigation devices, and the like.

Particularly, as a demand for smartphones has recently increased, the use of touchscreens, capable of providing various data input methods in a limited form factor, has increased.

Such touchscreens commonly include a substrate and a transparent electrode. According to the related art, a transparent electrode formed of indium tin oxide (ITO) has mainly been used therein. However, recently, a transparent electrode using a metal mesh has mainly been used.

The transparent electrode circuit using the metal mesh according to the related art is manufactured by forming a hard coating layer on a substrate in order to improve optical characteristics, chemical resistance, impact resistance, and the like, forming a metal electrode film on the hard coating layer, and then performing processes such as an exposing process, a developing process, an etching process, a delaminating process, and the like.

However, in the case in which the hard coating layer is formed on the substrate as described above, close adhesion between the substrate and a mesh pattern electrode is low, such that the transparent electrode circuit may not be appropriately formed.

The problem of the close adhesion as described above may be partially solved by forming the metal mesh on a primer layer. However, in this case, there may be another problem, in that chemical resistance or impact resistance of the exposed primer layer may be relatively weak.

The following Patent Document 1, which relates to an electrode of a touchscreen panel, discloses a configuration including a substrate and a metal mesh type electrode, but does not disclose a configuration in which insulating paste is filled in air gaps of the electrode to form a hard coating layer.

### RELATED ART DOCUMENT

(Patent Document 1) Korean Patent Laid-Open Publication No. 2013-0055831

### SUMMARY

An aspect of the present disclosure may provide a touch panel capable of improving close adhesion between a substrate and a mesh pattern electrode and chemical resistance or impact resistance of a primer layer, and a method of manufacturing the same.

According to an aspect of the present disclosure, a touch panel may include: a substrate; mesh pattern electrodes formed on the substrate; and hard coating layers formed on the substrate and filling air gaps of the mesh pattern electrode.

The touch panel may further include a primer layer interposed between the substrate and the mesh pattern electrode and the substrate and the hard coating layer.

The mesh pattern electrode may be formed of a plurality of fine conductive lines intersecting with each other.

The plurality of fine conductive lines may be formed of at least one metal selected from a group consisting of Ag, Al, Cr, Ni, Mo, and Cu, or an alloy of at least two metals selected from a group consisting of Ag, Al, Cr, Ni, Mo, and Cu.

The plurality of fine conductive lines may have a line width of 0.5 to 10 μm.

The mesh pattern electrodes and the hard coating layers may be formed on both surfaces of the substrate so as to oppose each other.

According to another aspect of the present disclosure, a method of manufacturing a touch panel may include: forming a mesh pattern electrode on a substrate, the mesh pattern electrode including a plurality of first electrodes extended in a first axis direction and a plurality of second electrodes extended in a direction intersecting with the first axis direction; applying insulating paste to the substrate so as to fill air gaps of the mesh pattern electrode, thereby forming a hard coating layer; and performing planarization so that upper surfaces of the mesh pattern electrode and the hard coating layer are positioned on the same plane.

The method may further include, before the forming of the mesh pattern electrode, forming a primer layer on the substrate.

In the forming of the mesh pattern electrode, the mesh pattern electrode may be formed of a plurality of fine conductive lines.

According to another aspect of the present disclosure, a method of manufacturing a touch panel may include: depositing an electrode film on a substrate; coating the electrode film with a photo resist and removing a region other than a mask pattern having a lattice shape to form a mesh pattern electrode on which a remaining photo resist is coated; applying insulating paste to the substrate so as to cover air gaps of the mesh pattern electrode and an upper portion of the mesh pattern electrode on which the remaining photo resist is coated, thereby forming a hard coating layer; and removing overflowing insulating paste from the remaining photo resist and the mesh pattern electrode so that upper surfaces of the mesh pattern electrode and the hard coating layer are positioned on the same plane, thereby performing planarization.

The method may further include, before the depositing of the electrode film, forming a primer layer on the substrate.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a perspective view showing an appearance of an electronic device including a touch panel according to an exemplary embodiment of the present disclosure;

FIG. 2 is a cross-sectional view schematically showing the touch panel according to the exemplary embodiment of the present disclosure;

FIGS. 3A through 3H are cross-sectional views sequentially showing an example of a method of manufacturing the touch panel of FIG. 2; and

FIG. 4 is a cross-sectional view schematically showing a touch panel according to another exemplary embodiment of the present disclosure.

### DETAILED DESCRIPTION

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like elements.

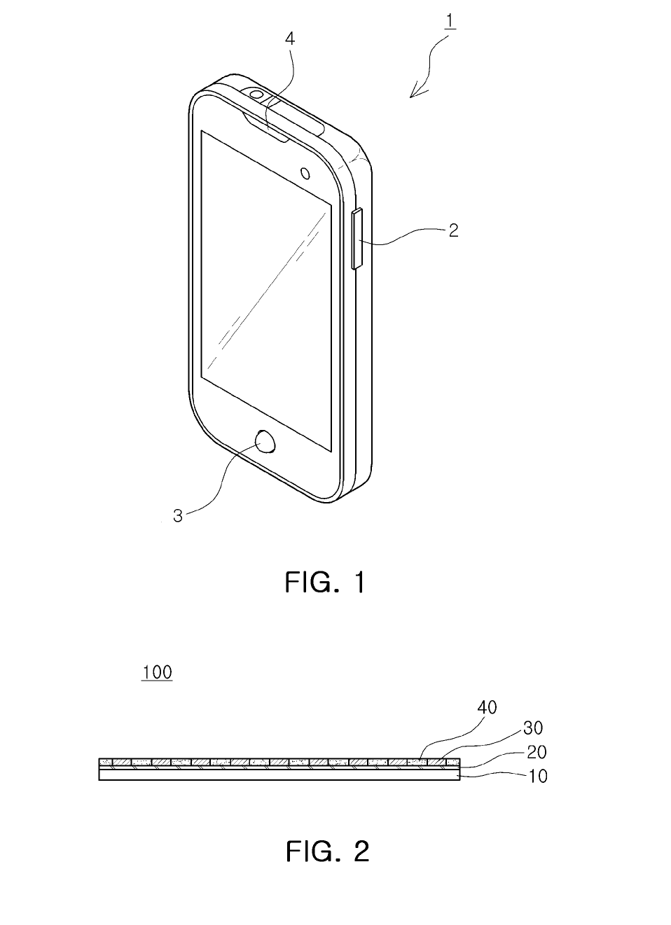

FIG. 1 is a perspective view showing an appearance of an electronic device including a touch panel according to an exemplary embodiment of the present disclosure.

Referring to FIG. 1, the electronic device 1 including the touch panel according to the exemplary embodiment of the present disclosure may include a display apparatus 2 outputting a screen, an inputting unit 3, an audio unit 4 outputting an audio, and the like.

The electronic device 1 may include a touchscreen apparatus integrated with the display apparatus 2, and the touch panel may be included in the touchscreen apparatus.

As shown in FIG. 1, in the case of a mobile device, the touchscreen apparatus may be generally provided in the state in which it is integrated with the display apparatus and needs to have light transmissivity high enough to transmit a screen displayed by the display apparatus 2.

Therefore, the touchscreen apparatus may be implemented by forming electrodes using a material having electrical conductivity on a transparent substrate formed of a material such as a polyethylene terephthalate (PET) film, a polycarbonate (PC) film, a polyethersulfone (PES) film, a polyimide (PI) film, a polymethlymethacrylate (PMMA) film, a cyclo-olefin polymer (COP) film, a soda glass, or a tempered glass.

In addition, wiring patterns connected to the electrodes formed of a transparent conductive material may be disposed in a bezel region of the display apparatus 2 and be visually shielded by the bezel region.

Since it is assumed that the touchscreen apparatus is operated in a capacitive scheme, the touchscreen apparatus may include a plurality of electrodes having a predetermined pattern.

In addition, the touchscreen apparatus may include a capacitance sensing circuit detecting change in capacitances generated in the plurality of electrodes, an analog-to-digital converting circuit converting an output signal of the capacitance sensing circuit into a digital value, a calculating circuit judging a touch using the data converted into the digital value, and the like.

FIG. 2 is a cross-sectional view schematically showing the touch panel according to the exemplary embodiment of the present disclosure.

Referring to FIG. 2, the touch panel 100 according to the exemplary embodiment of the present disclosure may include a substrate 10, a mesh pattern electrode 30 formed on the substrate 10, and a hard coating layer 40 formed on the substrate 10 and filling air gaps of the mesh pattern electrode 30.

Here, the substrate 10 and the mesh pattern electrode 30 and the substrate 10 and the hard core layer 40 may have a primer layer 20 interposed therebetween.

Although a structure in which the mesh pattern electrode 30 is formed on the primer layer 20 formed on the substrate 10 will be described in the following exemplary embodiment of the present disclosure for convenience of explanation, the present disclosure is not limited thereto. That is, the primer layer 20 may be omitted if necessary.

In the case of the touchscreen apparatus, the substrate 10 may provide a space in which the mesh pattern electrode 30 is to be formed, be a transparent substrate, and be formed of polyethylene terephthalate (PET). However, the present disclosure is not limited thereto.

Further, the substrate 10 may include a predetermined printed region formed thereon in order to visually shield a wiring generally formed of an opaque metal material with respect to a region in which a wiring connected to the mesh pattern electrode 30 is formed, in addition to a region in which the mesh pattern electrode 30 is formed.

The mesh pattern electrode 30 may apply a voltage to the substrate 10. In this case, a mesh pattern may be various patterns such as a rhombus pattern, a diamond pattern, a rectangular pattern, a triangular pattern, a circular pattern, and the like. However, the present disclosure is not limited to a specific pattern.

The mesh pattern electrode 30 may include first electrodes extended in a first axis direction and second electrodes extended in a second axis direction intersecting with the first axis direction.

The first and second electrodes may be formed on the substrate 10 by a vacuum depositing method such as a sputtering method and an E-Beam method, or an electrolysis method such as a plating method, or a process such as a printing process, an imprinting process, and the like.

Meanwhile, although not shown in FIG. 2, the mesh pattern electrode 30 may be electrically connected to a wiring pattern of a circuit board attached to one end of the substrate 10 through wirings and bonding pads.

Here, the circuit board may have a controller integrated circuit mounted thereon to detect a sensing signal generated in the mesh pattern electrode 30 and judge a touch from the sensing signal.

The controller integrated circuit may detect a change in capacitance generated in the mesh pattern electrode 30 by the touch and judge a touch from the change in capacitance.

In this case, the first electrode may be connected to a plurality of channels of the controller integrated circuit to receive a predetermined driving signal, wherein the channels may be used for the controller integrated circuit to detect the sensing signal.

Here, the controller integrated circuit may detect a change in capacitance generated between the first and second electrodes and use the change in capacitance as a sensing signal.

In the case in which a touching object is present on a cover lens to which a touch is applied or in a region adjacent to the cover lens, a capacitance may be changed between the first and second electrodes.

Since the first and second electrodes are formed of a conductive material, when a predetermined driving signal is applied to the first electrode, an electrical field may be formed between the first and second electrodes, and a change in the electrical field by the touching object may lead to a change in capacitance.

In addition, the mesh pattern electrode 30 according to the exemplary embodiment of the present disclosure may be formed of a plurality of fine conductive lines.

The plurality of fine conductive lines may be formed of at least one metal selected from a group consisting of Ag, Al, Cr, Ni, Mo, and Cu, or an alloy of at least two metals selected from a group consisting of Ag, Al, Cr, Ni, Mo, and Cu.

The mesh pattern electrode 30 is formed of a metal as described above, such that a resistance value of the mesh pattern electrode 30 may be decreased. Therefore, conductivity and detection sensitivity may be improved.

Here, the plurality of fine conductive lines may have a line width of 0.5 to 10 μm.

The reason is that a defective rate due to disconnection and a resistance value may be increased when the plurality of fine conductive lines have a line width narrower than 0.5 μm and transmissivity may be decreased when the plurality of fine conductive lines have a line width wider than 10 μm.

That is, the mesh pattern electrode 30 according to the exemplary embodiment of the present disclosure may generally have a mesh shape by the plurality of conductive fine lines formed in a net shape. Therefore, a phenomenon in which patterning marks are viewed in a region in which pattern electrodes are present according to related art may be decreased, and transmissivity of the touch panel may be improved.

An example of a method of manufacturing the touch panel configured as described above will be described below.

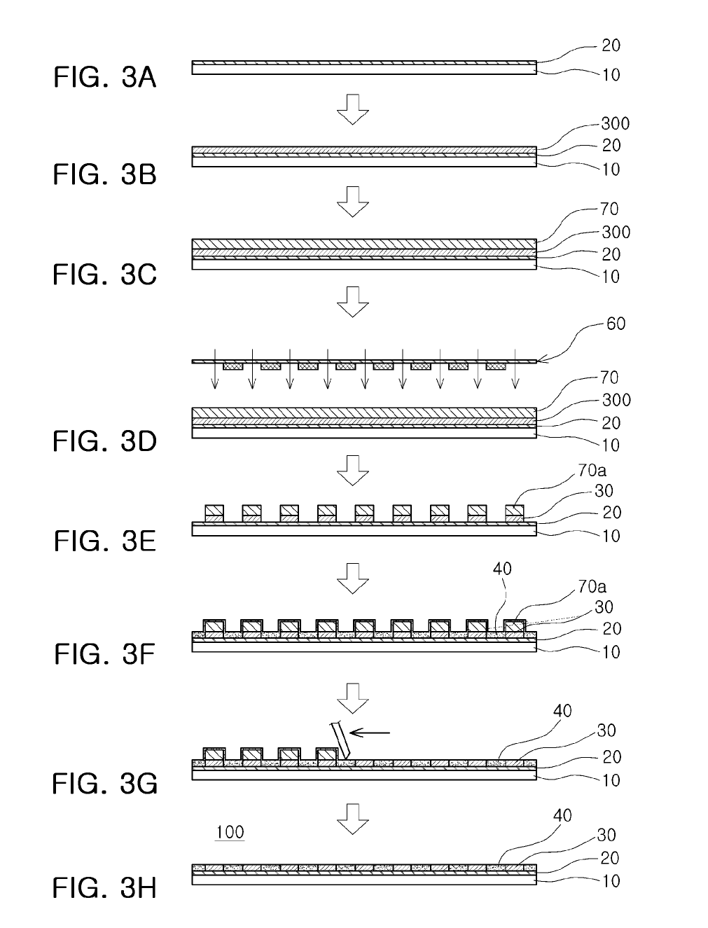

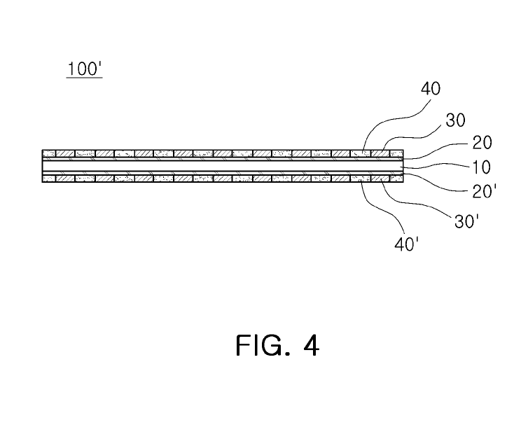

FIGS. 3A through 3H are cross-sectional views sequentially showing a method of manufacturing the touch panel of FIG. 2.

Referring to FIG. 3A, the substrate 10 may first be prepared.

Then, the primer layer 20 may be formed on the substrate 10.

Although a structure in which the mesh pattern electrode is formed on the primer layer 20 formed on the substrate 10 will be described in the following exemplary embodiment of the present disclosure for convenience of explanation, the present disclosure is not limited thereto. That is, the primer layer 20 may be omitted if necessary.

Next, the mesh pattern electrode 30 may be formed on the primer layer 20 formed on the substrate 10.

The mesh pattern electrode 30 may be formed by the following process. As shown in FIG. 3B, a mesh electrode film 300 may be deposited on the primer layer 20 formed on the substrate 10.

Then, as shown in FIG. 3C, a photo resist 70 may be coated on the electrode film 300.

Next, as shown in FIG. 3D, the photo resist 70 may be exposed and developed using an exposing device 60 to form a mask pattern having a lattice shape.

Then, as shown in FIG. 3E, when a region other than the mask pattern in the electrode film 300 is preferably etched and removed by a chemical method, the mesh pattern electrode 30 on which a remaining photo resist 70a is coated may be formed.

That is, the mesh pattern electrode 30 including a plurality of first electrodes extended in the first axis direction and a plurality of second electrodes extended in a direction intersecting with the first axis direction may be formed on the primer layer 20.

Here, the mesh pattern electrode 30 may be formed of a plurality of fine conductive lines.

In addition, the plurality of fine conductive lines may be formed of at least one metal selected from a group consisting of Ag, Al, Cr, Ni, Mo, and Cu, or an alloy of at least two metals selected from a group consisting of Ag, Al, Cr, Ni, Mo, and Cu.

Further, the plurality of conductor fin lines may be formed so that a line width thereof is preferably 0.5 to 10 μm. However, the present disclosure is not limited thereto.

Next, as shown in FIG. 3F, insulating pastes formed of a hard resin having a high degree of hardness, such as an acryl resin, an urethane based resin, a siloxane based resin, or the like, may be applied onto the primer layer 20 by a method such as a spin coating method, a dip coating method, or the like, so as to cover an upper portion of the mesh pattern electrode on which the remaining photo resist 70a is coated simultaneously with being filled in air gaps of the mesh pattern electrode 30, thereby forming the hard coating layer 40 having a thickness similar to that of the mesh pattern electrode 30.

Next, as shown in FIG. 3G, overflowing insulating paste from the remaining photo resist 70a and the mesh pattern electrode 30 may be removed so that upper surfaces of the mesh pattern electrode 30 and the hard coating layer 40 are positioned on the same plane, thereby completing the touch panel 100 as shown in FIG. 3H.

Due to the planarization process as described above, a problem in which the hard coating layer 40 completely or partially covers the mesh pattern electrode 30 may be solved.

In the touch panel 100 according to the exemplary embodiment of the present disclosure configured as described above, close adhesion between the substrate 10 or the primer layer 20 and the mesh pattern electrode 30 may be improved, and the air gap of the mesh pattern electrode 30 may be filled with the hard coating layer 40, such that chemical resistance and impact resistance of the primer layer 20 may be improved.

In addition, as a post-process, a protective layer formed of a polymer film, or the like, may be formed to cover the mesh pattern electrode 30, thereby preventing oxidation of the mesh pattern electrode 30. In this case, a phenomenon in which the protective is broken and damaged due to a step generated between the substrate 10 and the mesh pattern electrode 30 may occur.

However, according to the exemplary embodiment of the present disclosure, the step between the substrate 10 and the mesh pattern electrode 30 may be removed to prevent damage to the protective layer generated in the above-mentioned manufacturing process.

In addition, an inner wall of the air gap of the mesh pattern electrode 30 may be completely filled with the hard coating layer 40 to prevent the air gap of the mesh pattern electrode 30 from being corroded.

FIG. 4 is a cross-sectional view schematically showing a touch panel according to another exemplary embodiment of the present disclosure.

Referring to FIG. 4, the touch panel 100′ may include primer layers 20 and 20′, mesh pattern electrodes 30 and 30′, and hard coating layers 40 and 40′ each formed on both surfaces of a substrate 10 so as to face each other.

Here, since structures of the primer layer 20′, the mesh pattern electrode 30′, and the hard coating layer 40′ formed on a lower surface of the substrate 10 are the same as those of the primer layer 20, the mesh pattern electrode 30, and the hard coating layer 40 formed on an upper surface of the substrate 10 according to the exemplary embodiment of the present disclosure described above, a detailed description thereof will be omitted in order to avoid overlapped descriptions.

As set forth above, according to the exemplary embodiments of the present disclosure, the mesh pattern electrode is formed on the substrate and the insulating paste fill the air gap of the mesh pattern electrode to form the hard coating layer, whereby close adhesion between the substrate and the mesh pattern electrode may be improved. In addition, the primer layer is not exposed, whereby chemical resistance and impact resistance may be improved.

While exemplary embodiments have been shown and described above, it will be apparent to those skilled in the art that modifications and variations could be made without departing from the spirit and scope of the present disclosure as defined by the appended claims.

What is claimed is:

1. A touch panel comprising:
a substrate;
mesh pattern electrodes formed on the substrate; and
hard coating layers formed on the substrate and filling air gaps of the mesh pattern electrode.

2. The touch panel of claim 1, further comprising a primer layer interposed between the substrate and the mesh pattern electrode and the substrate and the hard coating layer.

3. The touch panel of claim 1, wherein the mesh pattern electrode is formed of a plurality of fine conductive lines intersecting with each other.

4. The touch panel of claim 3, wherein the plurality of fine conductive lines are formed of at least one metal selected from a group consisting of Ag, Al, Cr, Ni, Mo, and Cu, or an alloy of at least two metals selected from a group consisting of Ag, Al, Cr, Ni, Mo, and Cu.

5. The touch panel of claim 3, wherein the plurality of fine conductive lines have a line width of 0.5 to 10 μm.

6. The touch panel of claim 1, wherein the mesh pattern electrodes and the hard coating layers are formed on both surfaces of the substrate so as to oppose each other.

7. A method of manufacturing a touch panel, comprising:
forming a mesh pattern electrode on a substrate, the mesh pattern electrode including a plurality of first electrodes extended in a first axis direction and a plurality of second electrodes extended in a direction intersecting with the first axis direction;
applying insulating paste to the substrate so as to fill air gaps of the mesh pattern electrode, thereby forming a hard coating layer; and
performing planarization so that upper surfaces of the mesh pattern electrode and the hard coating layer are positioned on the same plane.

8. The method of claim 7, further comprising, before the forming of the mesh pattern electrode, forming a primer layer on the substrate.

9. The method of claim 7, wherein in the forming of the mesh pattern electrode, the mesh pattern electrode is formed of a plurality of fine conductive lines.

10. The method of claim 9, wherein the plurality of fine conductive lines are formed of at least one metal selected from a group consisting of Ag, Al, Cr, Ni, Mo, and Cu, or an alloy of at least two metals selected from a group consisting of Ag, Al, Cr, Ni, Mo, and Cu.

11. The method of claim 9, wherein the plurality of fine conductive lines are formed so that a line width thereof is 0.5 to 10 μm.

12. A method of manufacturing a touch panel, comprising:
depositing an electrode film on a substrate;
coating the electrode film with a photo resist and removing a region other than a mask pattern having a lattice shape to form a mesh pattern electrode on which a remaining photo resist is coated;
applying insulating paste to the substrate so as to cover air gaps of the mesh pattern electrode and an upper portion of the mesh pattern electrode on which the remaining photo resist is coated, thereby forming a hard coating layer; and
removing overflowing insulating paste from the remaining photo resist and the mesh pattern electrode so that upper surfaces of the mesh pattern electrode and the hard coating layer are positioned on the same plane, thereby performing planarization.

13. The method of claim 12, further comprising, before the depositing of the electrode film, forming a primer layer on the substrate.
